(19) United States
(12) Patent Application Publication
(10) Pub. No.: US 2024/0170353 A1
(43) Pub. Date: May 23, 2024

(54) SEMICONDUCTOR DEVICE AND MOUNTING STRUCTURE FOR SEMICONDUCTOR ELEMENT

(71) Applicant: ROHM CO., LTD., Kyoto-shi (JP)

(72) Inventor: Tsuyoshi TACHI, Kyoto-shi (JP)

(73) Assignee: ROHM CO., LTD., Kyoto-shi (JP)

(21) Appl. No.: 18/430,644

(22) Filed: Feb. 1, 2024

Related U.S. Application Data
(63) Continuation of application No. PCT/JP2022/031725, filed on Aug. 23, 2022.

(30) Foreign Application Priority Data
Sep. 14, 2021 (JP) 2021-149234

(51) Int. Cl. H01L 23/13; H01L 23/00; H01L 23/31; H01L 25/07; H01L 25/18; H05K 1/02; H05K 1/18

(52) U.S. Cl. CPC H01L 23/13; H01L 23/3121; H01L 24/13; H01L 24/16; H01L 25/072; H01L 25/18; H05K 1/0298; H05K 1/183; H01L 2224/13155; H01L 2224/13611; H01L 2224/16225; H01L 2924/13064; H01L 2924/181

(57) ABSTRACT

A semiconductor device includes: a substrate with an obverse surface facing in a thickness direction; first and second wirings on the obverse surface; and a semiconductor element with a first electrode facing the obverse surface and an adjacent second electrode facing the obverse surface. The first electrode is electrically bonded to the first wiring, and the second electrode bonded to the second wiring. The substrate includes first, second and third sections, with the first section including a portion of the obverse surface and overlapping with the first wiring and first electrode as viewed in the thickness direction. The second section includes a portion of the obverse surface, overlapping with the second wiring and second electrode as viewed in the thickness direction. The third section, located between the first and the second sections as viewed in the thickness direction, includes a first surface with its normal direction intersecting the thickness direction.

### CROSS-REFERENCE TO RELATED APPLICATIONS

This application is a continuation of International Application No. PCT/JP2022/031725, filed Aug. 23, 2022, which claims priority to Japanese Patent Application No. 2021-149234, filed Sep. 14, 2021, the entire contents of each are incorporated herein by reference.

### TECHNICAL FIELD

The present disclosure relates to a semiconductor device with a flip-mounted semiconductor element and also to a mounting structure for the semiconductor element.

### BACKGROUND ART

JP-A-2020-188085 discloses an example of a semiconductor device provided with a semiconductor element having a lateral structure (HEMT). The semiconductor element includes a first electrode and a second electrode. In the semiconductor device, the semiconductor element is mounted on a die pad. The first electrode and the second electrode are electrically connected via wires to a plurality of terminal leads disposed around the die pad.

To meet the recent demands for more compact semiconductor devices, the semiconductor element of JP-A-2020-188085 may be flip-chip mounted onto a wiring board or the like. In addition, the semiconductor element may be made be more compact by reducing the spacing between the first electrode and the second electrode. Reducing the spacing between the first electrode and the second electrode, however, involves reducing the spacing between the wirings to which the semiconductor element is electrically bonded. This will lower the dielectric strength of the wiring board or the like to which the semiconductor element is mounted. In view of the above, measures are needed for allowing the semiconductor element to be more compact while preventing reduction of the dielectric strength of the wiring board or the like.

### BRIEF DESCRIPTION OF THE DRAWINGS

FIG. 1 is a plan view of a semiconductor device according to a first embodiment of the present disclosure.

FIG. 2 is a plan view corresponding to FIG. 1 from which the sealing resin is omitted.

FIG. 3 is a plan view corresponding to FIG. 2 in which the semiconductor element and the IC are shown as transparent.

FIG. 4 is a bottom view of the semiconductor device shown in FIG. 1.

FIG. 5 is a sectional view taken along line V-V in FIG. 2.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a partially enlarged view of FIG. 3.

FIG. 10A is a partially enlarged view of FIG. 8.

FIG. 10B is a partially enlarged sectional view corresponding to FIG. 10A, showing another configuration of the substrate.

FIG. 11 is a partially enlarged sectional view of a variation of the semiconductor device shown in FIG. 1.

FIG. 12 is a sectional view of a semiconductor device according to a second embodiment of the present disclosure.

FIG. 13 is a partially enlarged view of FIG. 12.

FIG. 14 is a sectional view of a semiconductor device according to a third embodiment of the present disclosure.

FIG. 15 is a partially enlarged view of FIG. 14.

FIG. 16 is a partially enlarged sectional view of a variation of the semiconductor device shown in FIG. 14.

FIG. 17 is a plan view of a semiconductor device according to a fourth embodiment of the present disclosure.

FIG. 18 is a sectional view taken along line XVIII-XVIII in FIG. 17.

FIG. 19 is a sectional view taken along line XIX-XIX in FIG. 17.

FIG. 20 is a plan view of a semiconductor device according to the first embodiment of the present disclosure.

FIG. 21 is a sectional view taken along line XXI-XXI in FIG. 20.

FIG. 22 is a sectional view taken along line XXII-XXII in FIG. 20.

FIG. 23 is a sectional view taken along line XXIII-XXIII in FIG. 20.

FIG. 24 is a partially enlarged view of FIG. 23.

FIG. 25 is a plan view of a mounting structure for a semiconductor element according to the second embodiment of the present disclosure.

FIG. 26 is a sectional view taken along line XXVI-XXVI in FIG. 25.

### DETAILED DESCRIPTION OF EMBODIMENTS

Preferred embodiments of the present disclosure will be described with reference to the accompanying drawings.

### First Embodiment

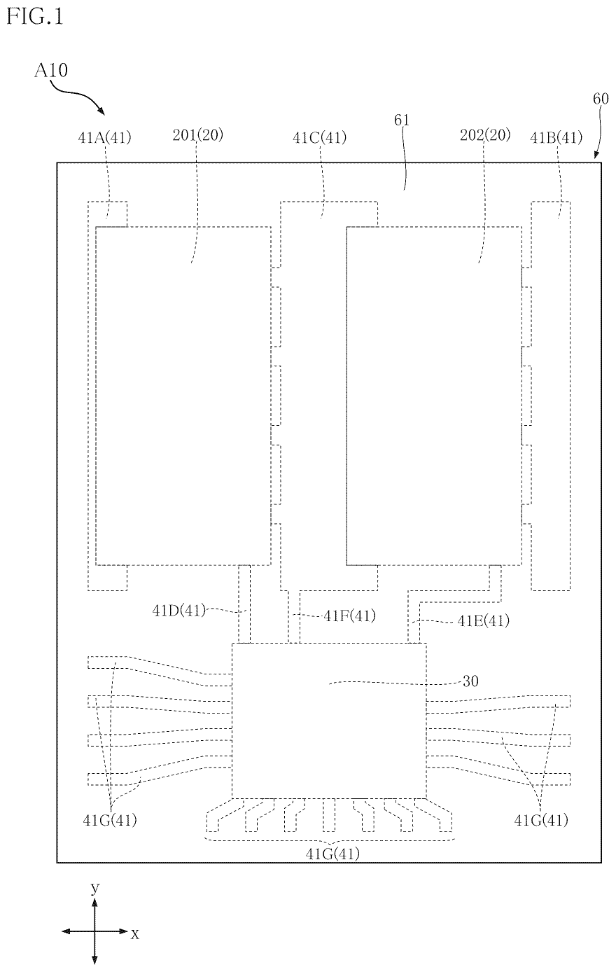

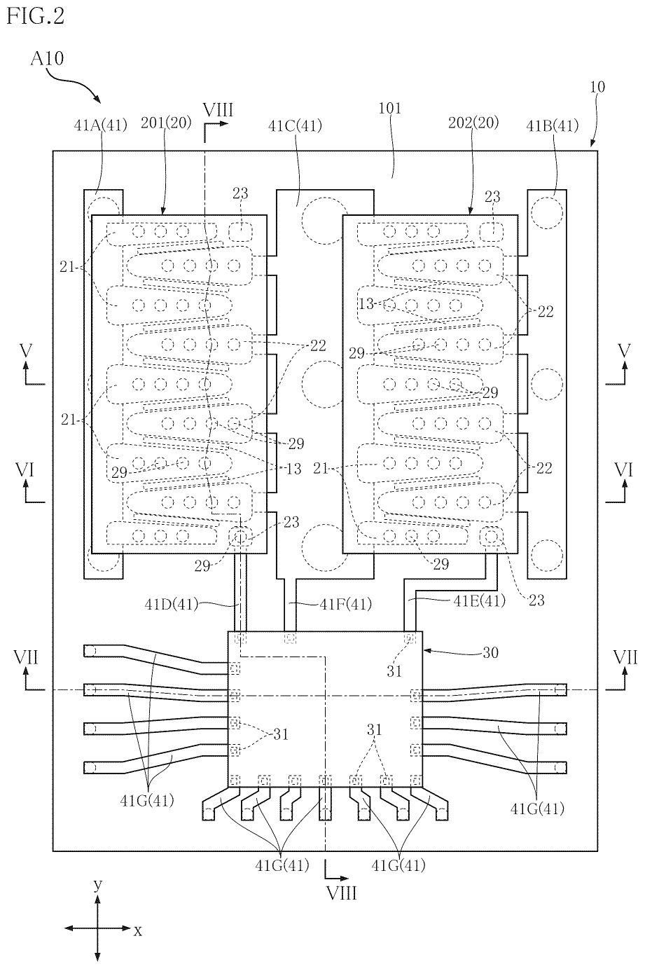

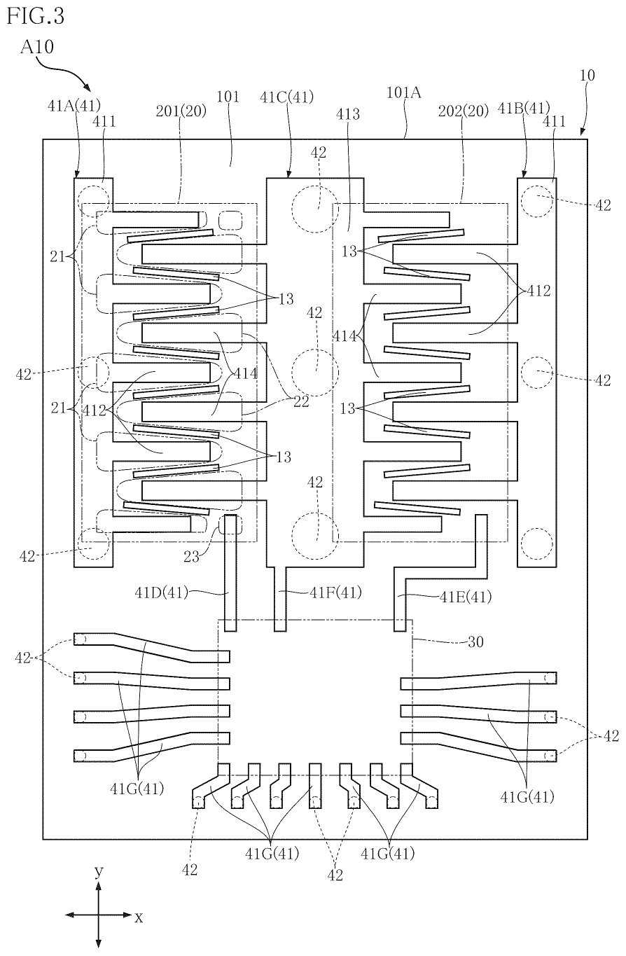

With reference to FIGS. 1 to 10B, a semiconductor device A10 according to a first embodiment of the present disclosure will be described. The semiconductor device A10 includes a substrate 10, a semiconductor element 20, a bonding layer 29, an IC 30, a plurality of wirings 41, a plurality of connecting wirings 42, a plurality of terminals 50, and a sealing resin 60. The semiconductor device A10 is provided in a resin package for surface mounting on a wiring board. The semiconductor device A10 converts an external supply of direct-current power into alternating-current power by the semiconductor element 20. The alternating-current power is supplied to a driving target such as a motor. For the convenience of description, FIG. 2 omits the sealing resin 60. For the convenience of description, FIG. 3 corresponding to FIG. 2 shows the semiconductor element 20 and the IC 30 as transparent. In FIG. 3, the outlines of the semiconductor element 20 and the IC 30 are indicated by an imaginary line (two-dot-dash line).

For the convenience of description of the semiconductor device A10, the thickness direction of the substrate 10 is referred to as a “thickness direction z”. A direction orthogonal to the thickness direction z is referred to as a “first direction x”. The direction orthogonal to the thickness direction z and the first direction x is referred to as a “second direction y”. As shown in FIG. 1, the semiconductor device A10 is rectangular as viewed in the thickness direction z.

As shown in FIGS. 2 to 4, the substrate 10 supports the wirings 41, the connecting wirings 42, and the terminals 50. The substrate 10 is electrically insulating. The substrate 10 is made of a material containing resin. An example of the resin is an epoxy resin.

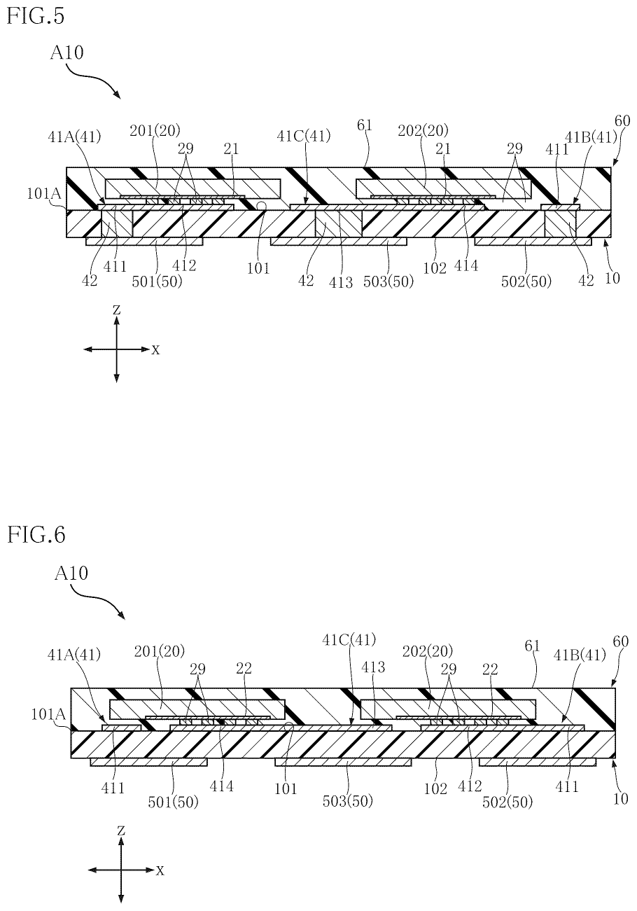

As shown in FIGS. 5 to 8, the substrate 10 has an obverse surface 101 and a reverse surface 102. The obverse surface 101 faces in the thickness direction z, and the reverse surface 102 faces the opposite in the thickness direction z. The reverse surface 102 is exposed to the outside of the semiconductor device A10. When the semiconductor device A10 is mounted on a wiring board, the reverse surface 102 faces the wiring board.

As shown in FIGS. 2, 5 and 6, the semiconductor element 20 faces the obverse surface 101 of the substrate 10. The semiconductor element 20 is a transistor (switching element) used mainly for the purpose of power conversion. The semiconductor element 20 is made of a material containing a nitride semiconductor. For the semiconductor device A10, the semiconductor element 20 is a high electron mobility transistor (HEMT) made of a material containing gallium nitride (GaN). The semiconductor element 20 includes a first element 201 and a second element 202. The first element 201 and the second element 202 are spaced apart from each other in the first direction x.

As shown in FIGS. 2 and 8, the semiconductor element 20 includes a plurality of first electrodes 21, a plurality of second electrodes 22, and two third electrodes 23. The first electrodes 21, the second electrodes 22, and the two third electrodes 23 face the obverse surface 101 of the substrate 10.

As shown in FIG. 2, the first electrodes 21 and the second electrodes 22 extend in the first direction x. The first electrodes 21 and the second electrodes 22 are alternately arranged in the second direction y. The first electrodes 21 pass the electric current corresponding to the power before conversion by the semiconductor element 20. That is, the first electrodes 21 correspond to the drains of the semiconductor element 20. The second electrodes 22 pass the electric current corresponding to the power after conversion by the semiconductor element 20. That is, the second electrodes 22 correspond to the sources of the semiconductor element 20.

As shown in FIG. 2, the two third electrodes 23 are arranged on the opposite sides of the semiconductor element 20 in the second direction y. One of the two third electrodes 23 receives a gate voltage applied for driving the semiconductor element 20. As viewed in the thickness direction z, the third electrodes 23 are smaller in area than the first electrodes 21 and the second electrodes 22. Note that these shapes and arrangement of the first electrodes 21, the second electrodes 22, and the two third electrodes 23 in the semiconductor element 20 are cited by way of example and without limitation.

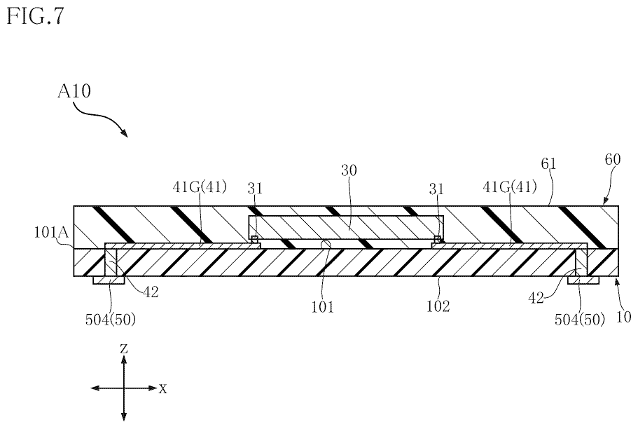

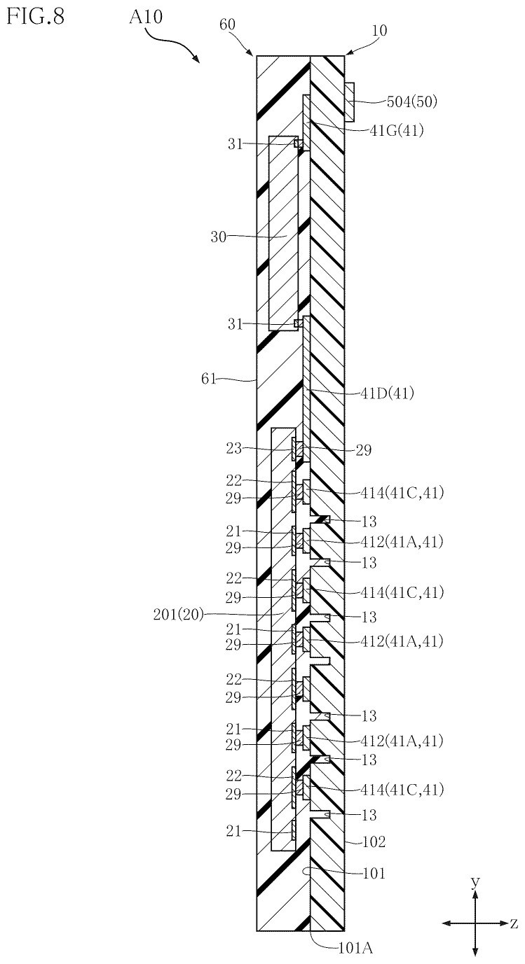

As shown in FIGS. 2 and 7, the IC 30 faces the obverse surface 101 of the substrate 10. The IC 30 is a gate driver that applies a gate voltage to the third electrodes 23 of the semiconductor element 20 (the first element 201 and the second element 202). The IC 30 includes a plurality of electrodes 31. The electrodes 31 face the obverse surface 101.

As shown in FIGS. 3 and 5 to 8, the wirings 41 are disposed on the obverse surface 101 of the substrate 10. The composition of the wirings 41 includes copper (Cu), for example. The wirings 41, together with the connecting wirings 42 and the terminals 50, form conduction paths connecting the semiconductor element 20 and the IC 30 to a wiring board on which the semiconductor device A10 is mounted.

As shown in FIG. 3, the wirings 41 include an input wiring 41A, a ground wiring 41B, an output wiring 41C, a first gate wiring 41D, a second gate wiring 41E, a potential wiring 41F, and a plurality of control wirings 41G.

As shown in FIG. 3, the input wiring 41A and the ground wiring 41B are spaced apart from each other in the first direction x. The input wiring 41A and the ground wiring 41B each include a first base portion 411 and a plurality of first extending portion 412. The first base portion 411 extends in the second direction y. The first extending portions 412 extend from the first base portion 411 in the first direction x toward a second base portion 413 of the output wiring 41C, which will be described later. The first extending portions 412 are arranged side by side in the second direction y.

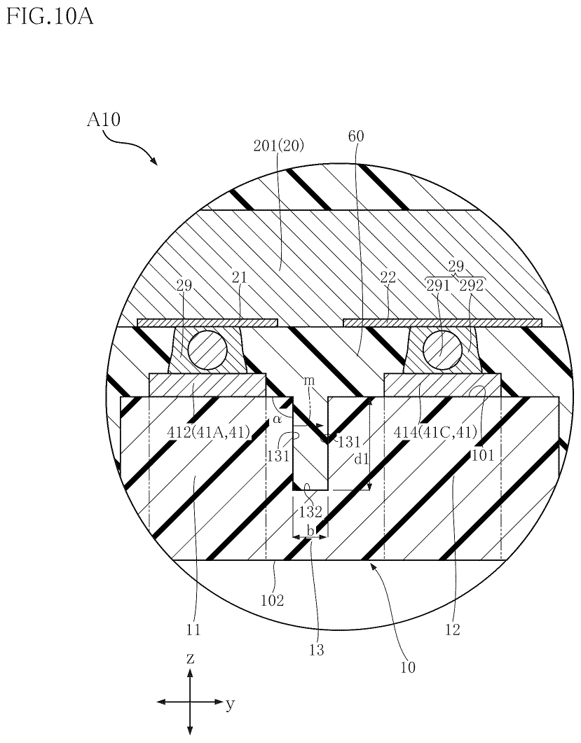

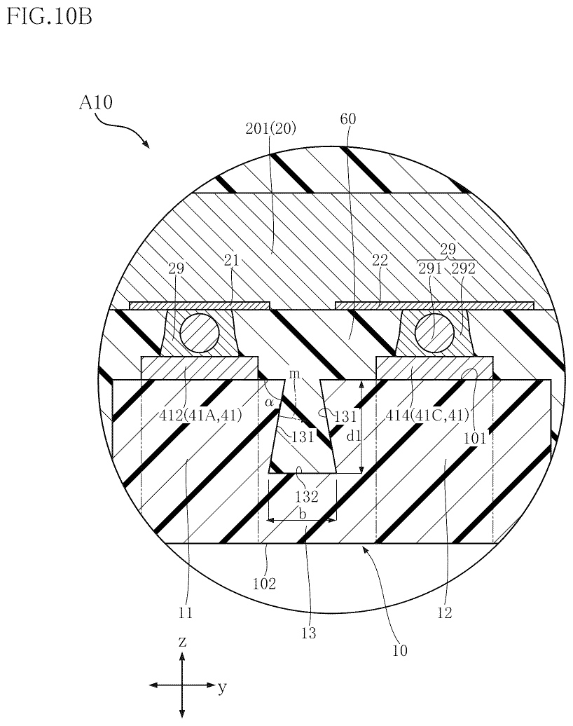

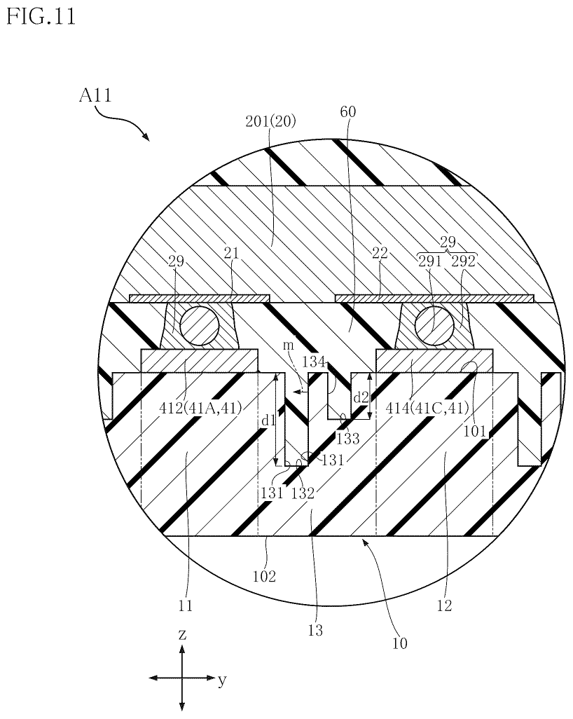

As shown in FIG. 5, the first electrodes 21 of the first element 201 are electrically bonded to the first extending portions 412 of the input wiring 41A via the bonding layer 29. As shown in FIG. 6, the second electrodes 22 of the second element 202 are electrically bonded to the first extending portions 412 of the ground wiring 41B via the bonding layer 29. The composition of the bonding layer 29 includes tin (Sn). As shown in FIG. 10A, the bonding layer 29 includes a metal core 291 and a metal layer 292. The metal layer 292 covers the metal core 291. The composition of the metal core 291 includes nickel (Ni), and the composition of the metal layer 292 includes tin. The bonding layer 29 is what is commonly called a solder ball.

As shown in FIG. 3, the output wiring 41C is located between the first base portion 411 of the input wiring 41A and the first base portion 411 of the ground wiring 41B in the first direction x. The output wiring 41C includes a second base portion 413 and a plurality of second extending portions 414. The second base portion 413 extends in the second direction y. The second extending portions 414 extend in the first direction x from the both ends of the second base portion 413 in the first direction x toward the first base portion 411 of the input wiring 41A or the first base portion 411 of the ground wiring 41B. The second extending portions 414 are arranged side by side in the second direction y.

As shown in FIG. 6, the second electrodes 22 of the first element 201 are electrically bonded to a plurality of second extending portions 414 of the output wiring 41C via the bonding layer 29. As shown in FIG. 5, the first electrodes 21 of the second element 202 are electrically bonded to a plurality of second extending portions 414 of the output wiring 41C via the bonding layer 29. This electrically connects the first electrodes 21 of the second element 202 to the second electrodes 22 of the first element 201.

As shown in FIG. 8, one of the two third electrodes 23 of the first element 201 is electrically bonded to the first gate wiring 41D via the bonding layer 29. As shown in FIG. 2, one of the two third electrodes 23 of the second element 202 is electrically bonded to the second gate wiring 41E via the bonding layer 29.

As shown in FIGS. 2 and 3, the potential wiring 41F is connected to the second base portion 413 of the output wiring 41C. The potential wiring 41F is used for setting the ground for the gate voltage applied by the IC 30 to the third electrodes 23 of the first element 201.

As shown in FIGS. 2, 7 and 8, the electrodes 31 of the IC 30 are electrically bonded to the first gate wiring 41D, the second gate wiring 41E, the potential wiring 41F, and the control wirings 41G. This electrically connects the IC 30 to the third electrodes 23 of the first element 201 and the second element 202, and the output wiring 41C.

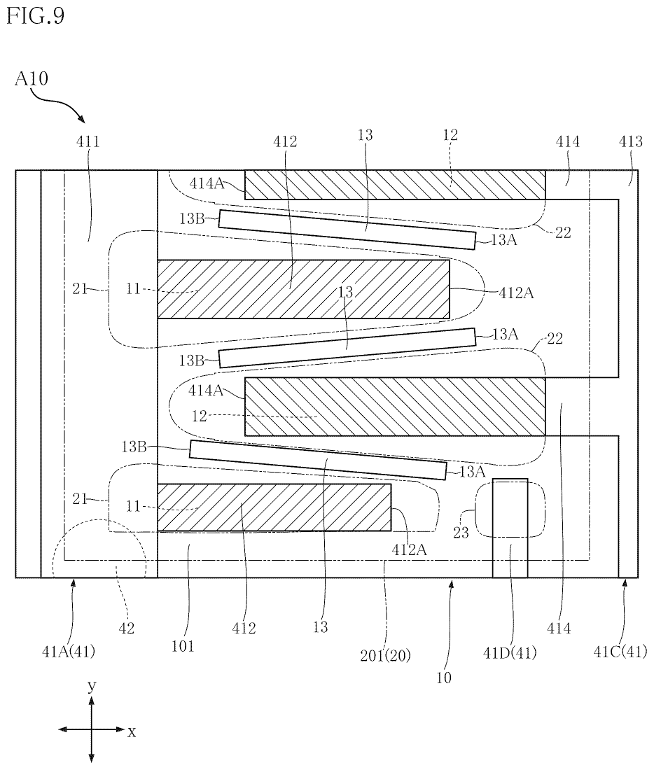

As shown in FIGS. 9 and 10A, the substrate 10 includes a plurality of first sections 11, a plurality of second sections 12, and a plurality of third sections 13. As viewed in the thickness direction z, the first sections 11, the second sections 12, and the third sections 13 overlap with the semiconductor element 20. The description below of the first sections 11, the second sections 12, and the third sections 13 is directed to those overlapping with the first element 201 of the semiconductor element 20.

As shown in FIGS. 9 and 10A, the first sections 11 include portions of the obverse surface 101 of the substrate 10. As viewed in the thickness direction z, each first section 11 overlaps with one of the first electrodes 21 of the first element 201 and one of the first extending portions 412 of the input wiring 41A. In FIG. 9, the first sections 11 are shaded with diagonal lines.

As shown in FIGS. 9 and 10A, the second sections 12 include portions of the obverse surface 101 of the substrate 10. As viewed in the thickness direction z, each second section 12 overlaps with one of the second electrodes 22 of the first element 201 and one of the second extending portions 414 of the output wiring 41C. In FIG. 9, the second sections 12 are shaded with diagonal lines.

As shown in FIG. 9, each third section 13 is located between a first section 11 and a second section 12 adjacent to each other as viewed in the thickness direction z. The third sections 13 extend in a direction orthogonal to the thickness direction z. As shown in FIG. 3, in the substrate 10, the third sections 13 are located away from the outer edges 101A of the obverse surface 101 as viewed in the thickness direction z.

As shown in FIG. 9, each third section 13 has a first end 13A and a second end 13B. The first end 13A and the second end 13B are located on the opposite sides in the direction in which the third section 13 extends. As viewed in the thickness direction z, the first end 13A is located between the first edge 412A of each first extending portion 412 of the input wiring 41A and the second base portion 413 of the output wiring 41C. As viewed in the thickness direction z, the second end 13B is located between the first base portion 411 of the input wiring 41A and the second edge 414A of each second extending portion 414 of the output wiring 41C.

As shown in FIG. 10A, each third section 13 has a first surface 131 and a second surface 132. The normal direction m to the first surface 131 intersects the thickness direction z. In the configuration shown in FIG. 10A, the normal direction m is perpendicular to the thickness direction z. Hence, the inclination angle α of the first surface 131 relative to the obverse surface 101 of the substrate 10 is 90°. The first surface 131 is connected to the obverse surface 101. The first surface 131 includes a pair of regions spaced apart from each other. The direction in which the two regions are spaced apart is equal to the direction in which the first electrodes 21 and the second electrodes 22 of the first element 201 are spaced apart. The second surface 132 faces the same side as the obverse surface 101 in the thickness direction z. The second surface 132 is connected to the first surface 131.

As shown in FIG. 10A, the first surface 131 and the second surface 132 of each third section 13 are located on the side opposite the first element 201 in the thickness direction z with the obverse surface 101 of the substrate 10 interposed therebetween. That is, each third section 13 includes a trench defined by the first surface 131 and the second surface 132 and recessed from the obverse surface 101. The first surface 131 has a length d1 in the thickness direction z, and the second surface 132 has a length b in the direction in which the first electrodes 21 and the second electrodes 22 of the first element 201 are spaced apart, where the length d1 is greater than the length b.

FIG. 10B shows a third section 13 of another configuration. In this configuration, the normal direction m to the first surface 131 intersects the thickness direction z but not perpendicularly to the thickness direction z. The inclination angle α of the first surface 131 to the obverse surface 101 of the substrate 10 is no smaller than 70° and no greater than 110°. More preferably, the inclination angle α is no smaller than 80° and no greater than 100°.

As shown in FIGS. 5 and 7, the connecting wirings 42 are embedded in the substrate 10. The both ends of each connecting wiring 42 in the thickness direction z are exposed at the obverse surface 101 and the reverse surface 102 of the substrate 10. Each connecting wiring 42 is connected to a wiring 41 other than the first gate wiring 41D, the second gate wiring 41E, and the potential wiring 41F. In addition, each connecting wiring 42 is connected to a terminal 50. This electrically connects each terminal 50 to one of the input wiring 41A, the ground wiring 41B, the output wiring 41C, and the control wirings 41G. The composition of the connecting wirings 42 includes copper, for example.

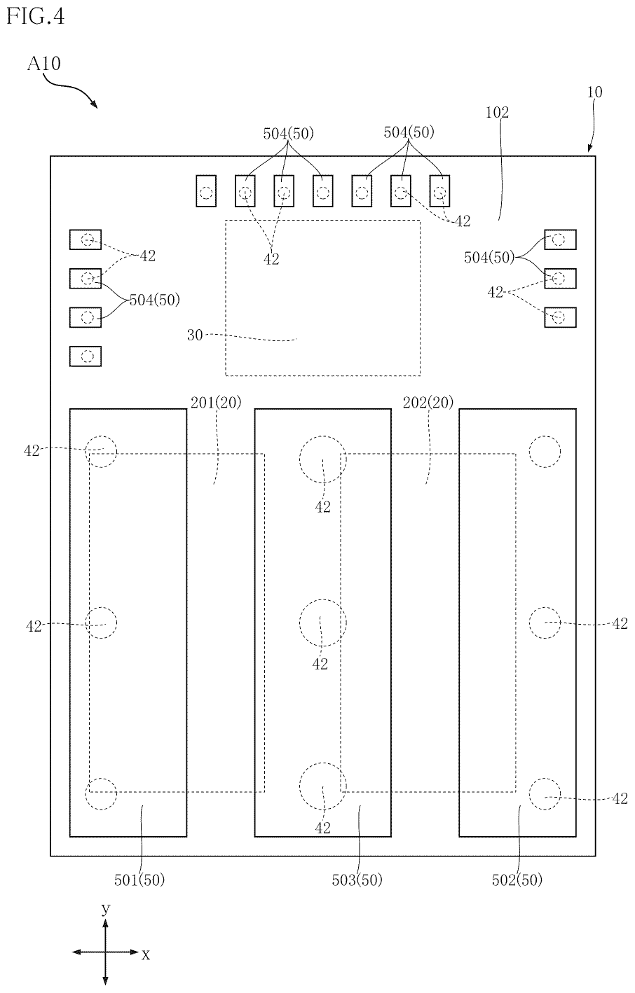

As shown in FIGS. 4 to 8, the terminals 50 are disposed on the reverse surface 102 of the substrate 10. The semiconductor device A10 is mounted onto a wiring board by soldering the terminals 50 to the wiring board. The terminals 50 include a plurality of metal layers. The metal layers include a nickel layer and a gold (Au) layer deposited on the reverse surface 102 in the stated order. In another example, the metal layers may include a nickel layer, a palladium (Pd) layer, and a gold layer deposited on the reverse surface 102 in the stated order.

As shown in FIG. 4, the plurality of terminals 50 include an input terminal 501, a ground terminal 502, an output terminal 503, and a plurality of control terminals 504.

The input terminal 501 is electrically connected to the input wiring 41A. The ground terminal 502 is electrically connected to the ground wiring 41B. The input terminal 501 and the ground terminal 502 are used to input a direct-current power to be converted by the semiconductor element 20. The input terminal 501 is a positive electrode (P terminal). The ground terminal 502 is a negative electrode (N terminal).

The output terminal 503 is electrically connected to the output wiring 41C. The output terminal 503 outputs an alternating-current power converted by the semiconductor element 20.

The control terminals 504 are electrically connected to the IC 30 via the control wirings 41G. One of the control terminals 504 receives power for driving the IC 30. One of the control terminals 504 receives an electrical signal directed to the IC 30. One of the control terminals 504 outputs an electrical signal from the IC 30.

The sealing resin 60 covers the semiconductor element 20, the IC 30, and the wirings 41 as shown in FIG. 1 and FIGS. 5 to 8. As shown in FIG. 10A, the sealing resin 60 is in contact with the obverse surface 101 of the substrate 10 and the first surface 131 and the second surface 132 of each third section 13 of the substrate 10. That is, in the semiconductor device A10, the sealing resin 60 fills out the trenches formed in the third sections 13.

The sealing resin 60 is electrically insulating. The sealing resin 60 is made of a material containing a black epoxy resin, for example. As shown in FIGS. 1 and 5 to 8, the sealing resin 60 has a top surface 61. The top surface 61 faces the same side as the obverse surface 101 of the substrate 10 in the thickness direction z.

Variation of First Embodiment:

With reference to FIG. 11, the following describes a semiconductor device A11 that is a variation of the semiconductor device A10. Note that FIG. 11 shows the same position as FIG. 10A.

The semiconductor device A11 differs from the semiconductor device A10 in the configuration of the third sections 13 of the substrate 10. As shown in FIG. 11, each third section 13 additionally has a third surface 133 and a fourth surface 134. The third surface 133 faces the same side as the obverse surface 101 of the substrate 10 in the thickness direction z. The fourth surface 134 faces in a direction orthogonal to the thickness direction z and is connected to the third surface 133 and the obverse surface 101. The fourth surface 134 includes a pair of regions spaced apart from each other. The direction in which the two regions are spaced apart is equal to the direction in which the first electrodes 21 and the second electrodes 22 of the first element 201 are spaced apart.

As shown in FIG. 11, for each third section 13, the third surface 133 is spaced apart from the second surface 132 as viewed in the thickness direction z. That is, each third section 13 includes one trench that is defined by the first surface 131 and the second surface 132 and recessed from the obverse surface 101 of the substrate 10, and another trench that is defined by the third surface 133 and the fourth surface 134 and recessed from the obverse surface 101.

As shown in FIG. 11, the third surface 133 of each third section 13 is located between the obverse surface 101 of the substrate 10 and the second surface 132 in the thickness direction z. That is, for each third section 13, the fourth surface 134 has a length d2 in the thickness direction z, and the first surface 131 has a length d1 in the thickness direction z, where the length d2 is smaller than the length d1. In addition, the length d2 is greater than the length of the third surface 133 in the direction in which the first electrodes 21 and the second electrodes 22 of the first element 201 are spaced apart.

Next, effects of the semiconductor device A10 will be described.

In the semiconductor device A10, the substrate 10 includes the first sections 11, the second sections 12, and the third sections 13. The first sections 11 include portions of the obverse surface 101 of the substrate 10 and overlap with the relevant wirings 41 and the first electrodes 21 of the semiconductor element 20 as viewed in the thickness direction z. The second sections 12 include portions of the obverse surface 101 and overlap with the relevant wirings 41 and the second electrodes 22 of the semiconductor element 20 as viewed in the thickness direction z. Each third section 13 is located between a first section 11 and a second section 12 as viewed in the thickness direction z. The third section 13 has a first surface 131, and the normal direction m to the first surface 131 intersects the thickness direction z. In the illustrated example, although the present disclosure is not limited to this, the normal direction m and the thickness direction z are orthogonal to each other. With this configuration, the creepage distance of the substrate 10 from a first section 11 to a second section 12 (the length of the path along the surface of the substrate 10) can be increased. This allows the spacing between the adjacent first and second electrodes 21 and 22 to be reduced to make the semiconductor element 20 more compact, without reducing the creepage distance of the substrate 10 from the wiring 41 overlapping with the first electrode 21 to the wiring 41 overlapping with the second electrode 22 as viewed in the thickness direction z. That is, the semiconductor device A10 allows the semiconductor element 20 to be more compact while preventing reduction of the dielectric strength of the semiconductor device A10.

Each third sections 13 of the substrate 10 has a second surface 132 facing the same side as the obverse surface 101 of the substrate 10 in the thickness direction z. In the semiconductor device A10, the first surface 131 and the second surface 132 of the third section 13 is located on the side opposite the semiconductor element 20 in the thickness direction z with the obverse surface 101 interposed therebetween. That is, the third section 13 includes a trench defined by the first surface 131 and the second surface 132 and recessed from the obverse surface 101. Notably, as shown in FIG. 10A, the length d1 of the first surface 131 in the thickness direction z is greater than the length b of the second surface 132 in the direction in which the first electrodes 21 and the second electrodes 22 of the semiconductor element 20 are spaced apart. This configuration is effective for increasing the creepage distance of the substrate 10 from the first section 11 to the second section 12.

The manufacture of the semiconductor device A10 involves bonding the semiconductor element 20 to the wirings 41. In this process, the bonding layer 29 may melt and flow out of the wirings 41, in the case where solder is contained in the bonding layer 29 at least partly. The melted bonding layer 29, however, flows into the trenches in the third sections 13 of the substrate 10 and does not spread further. This can prevent the bonding layer 29 from short-circuiting the wirings 41.

As viewed in the thickness direction z, the third sections 13 of the substrate 10 are located away from the outer edges 101A of the obverse surface 101 of the substrate 10. Thus, the trenches in the third sections 13 have a closed shape surrounded by the first surface 131. This configuration is effective for preventing decrease of the mechanical strength of the substrate 10.

The semiconductor device A10 further includes the bonding layer 29 that electrically bonds the wirings 41 to the first electrodes 21 and the second electrodes 22 of the semiconductor element 20. The bonding layer 29 includes a metal core 291 and a metal layer 292 covering the metal core 291. The composition of the metal layer 292 includes tin. In the process of bonding the semiconductor element 20 to the wirings 41 during the manufacture of the semiconductor device A10, the metal layer 292 may melt but the metal core 291 remains present between a wiring 41 and the first electrode 21 or the second electrode 22 and supports the semiconductor element 20. This ensures that spaces are left between the wirings 41 and the first and second electrodes 21 and 22.

The semiconductor device A10 further includes the sealing resin 60 that covers the semiconductor element 20. The sealing resin 60 is in contact with the first surface 131 of each third section 13 of the substrate 10. This configuration is effective for preventing reduction of the dielectric strength of the semiconductor device A10. In addition, the sealing resin 60 serves also as a reinforcement for the substrate 10.

The semiconductor device A10 further includes the terminals 50 disposed on the reverse surface 102 of the substrate 10 and the connecting wirings 42 embedded in the substrate 10. The connecting wirings 42 are connected to the relevant wirings 41 and the terminals 50. Although the wirings 41 are entirely covered with the sealing resin 60, this configuration can provide conductive paths from the wirings 41 to a wiring board on which the semiconductor device A10 is mounted without the need to increase the dimensions of the semiconductor device A10.

### Second Embodiment

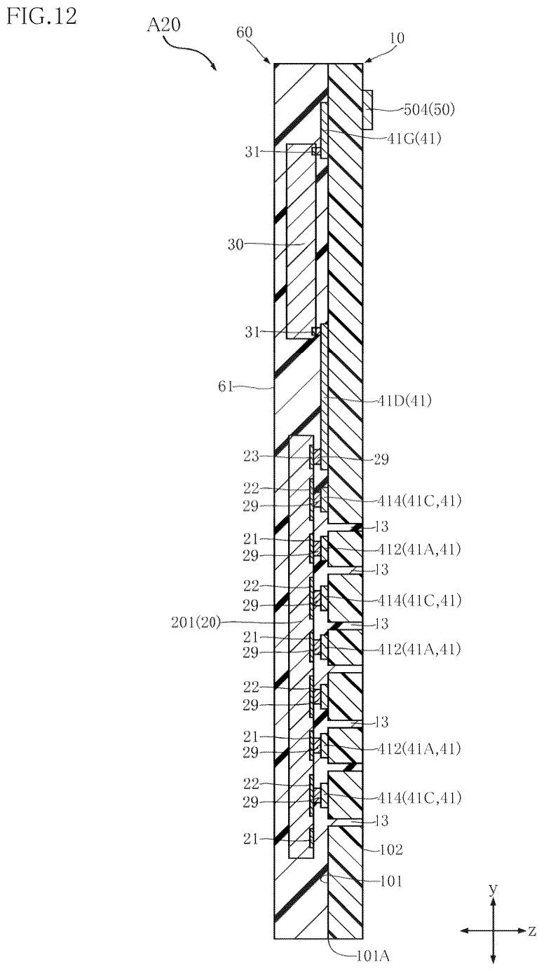

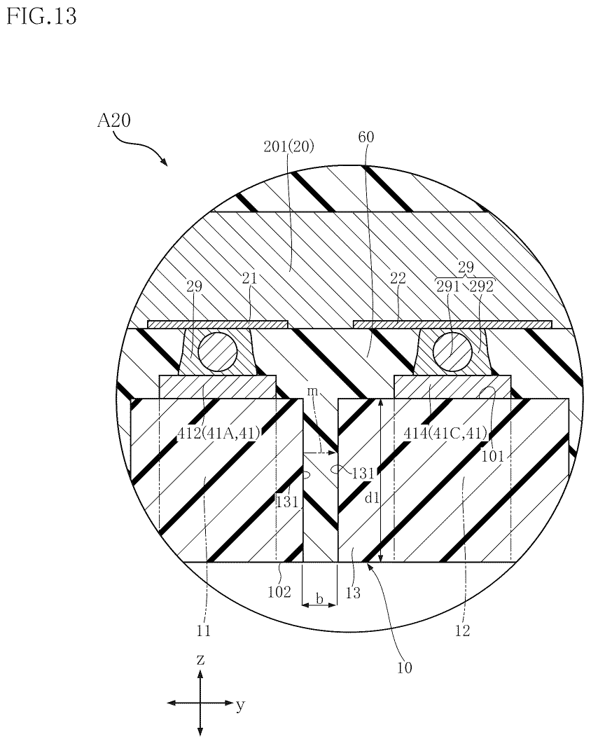

With reference to FIGS. 12 and 13, a semiconductor device A20 according to a second embodiment of the present disclosure will be described. In these figures, the same or similar elements as those of the semiconductor device A10 described above are denoted by the same reference numerals, and redundant descriptions are omitted. Note that FIG. 12 shows the same position as FIG. 8 showing the semiconductor device A10.

The semiconductor device A20 differs from the semiconductor device A10 in the configuration of the third sections 13 of the substrate 10.

As shown in FIG. 13, each third section 13 of this embodiment has a first surface 131 connected to the obverse surface 101 and the reverse surface 102 of the substrate 10. That is, the third sections 13 do not have a second surface 132. As shown in FIG. 12, the third section 13 includes a slit defined by the first surface 131 and penetrating the substrate 10 in thickness direction z.

Next, effects of the semiconductor device A20 will be described.

In the semiconductor device A20, the substrate 10 includes the first sections 11, the second sections 12, and the third sections 13. The first sections 11 include portions of the obverse surface 101 of the substrate 10 and overlap with the relevant wirings 41 and the first electrodes 21 of the semiconductor element 20 as viewed in the thickness direction z. The second sections 12 include portions of the obverse surface 101 and overlap with the relevant wirings 41 and the second electrodes 22 of the semiconductor element 20 as viewed in the thickness direction z. Each third section 13 is located between a first section 11 and a second section 12 as viewed in the thickness direction z. The third section 13 has a first surface 131, and the normal direction m to the first surface 131 intersects (or orthogonal to) the thickness direction z. That is, the semiconductor device A20 allows the semiconductor element 20 to be more compact while preventing reduction of the dielectric strength of the semiconductor device A20. Further, the semiconductor device A20 has a similar configuration as the semiconductor device A10 and thus achieves the same effect by such a configuration.

In the semiconductor device A20, the substrate 10 includes the third sections 13 each having a first surface 131 connected to the obverse surface 101 and the reverse surface 102. Thus, the length d1 of the first surface 131 in the thickness direction z is greater than the length d1 of the first surface 131 of the semiconductor device A10. This means that the substrate 10 of this embodiment has a greater creepage distance from the first section 11 to the second section 12 than that of the semiconductor device A10, and this enables the semiconductor device A20 to prevent reduction of the dielectric strength more effectively.

In the semiconductor device A20, the substrate 10 includes the third sections 13 each formed with a slit defined by the first surface 131 and penetrating the substrate 10 in the thickness direction z. The manufacture of the semiconductor device A20 involves bonding the semiconductor element 20 to the wirings 41. In this process, the bonding layer 29 may melt and flow out of the wirings 41, in the case where solder is contained in the bonding layer 29 at least partly. The melted bonding layer 29, however, flows into the slits formed in the third sections 13 and does not spread further. This can prevent the bonding layer 29 from short-circuiting the wirings 41. Due to the difference in the length d1 of the first surface 131 in the thickness direction z, the semiconductor device of the present embodiment can achieve a greater effect than the semiconductor device A10.

### Third Embodiment

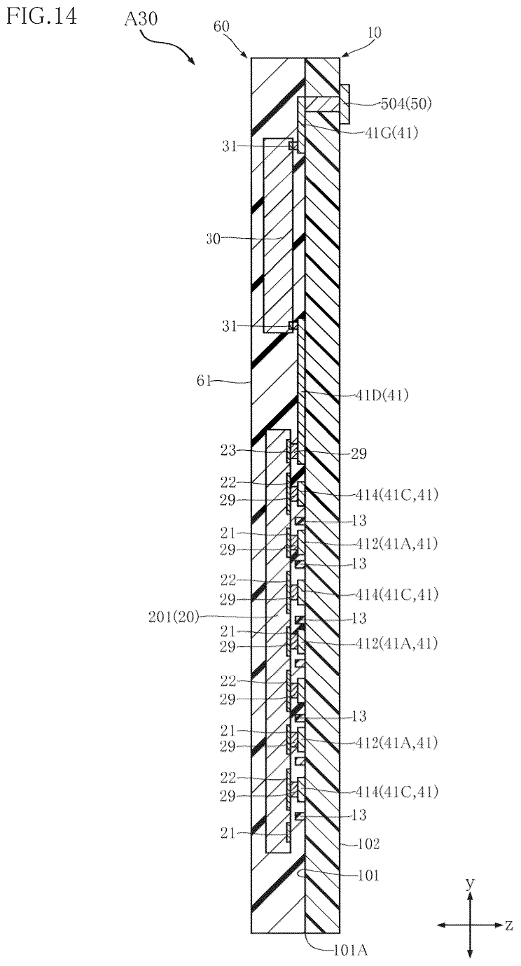

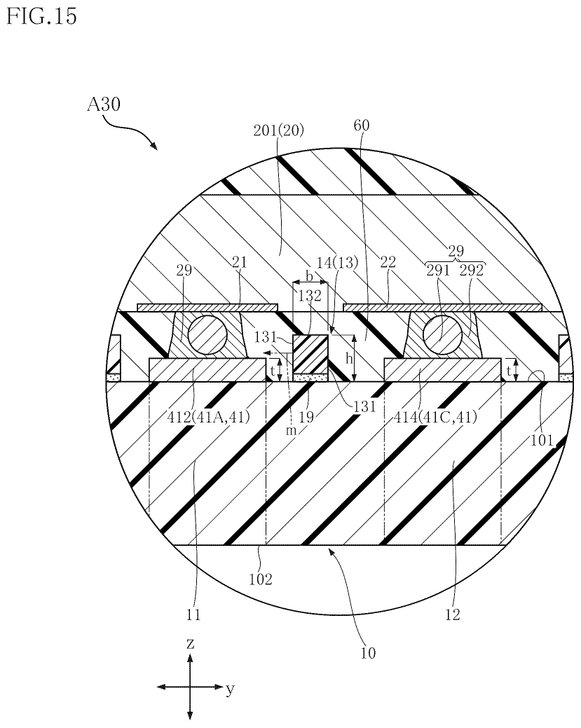

With reference to FIGS. 14 and 15, a semiconductor device A30 according to a third embodiment of the present disclosure will be described. In these figures, the same or similar elements as those of the semiconductor device A10 described above are denoted by the same reference numerals, and redundant descriptions are omitted. Note that FIG. 14 shows the same position as FIG. 8 showing the semiconductor device A10.

The semiconductor device A30 differs from the semiconductor device A10 in the configuration of the third sections 13 of the substrate 10.

As shown in FIG. 15, each third section 13 has the first surface 131 and the second surface 132 located between the obverse surface 101 of the substrate 10 and the first element 201. The second surface 132 is located on the side opposite the obverse surface 101 in the thickness direction z with the first surface 131 interposed therebetween. That is, as shown in FIG. 14, each third section 13 includes a ridge defined by the first surface 131 and the second surface 132 and raised from the obverse surface 101.

As shown in FIG. 15, each third sections 13 includes a projection 14 having a first surface 131 and a second surface 132. The projections 14 are made of an insulating material. The projections 14 are bonded to the obverse surface 101 of the substrate 10 via an adhesive layer 19. The projections 14 form the ridges included in the third sections 13. Alternatively, the third sections 13 may be integrally formed parts of the substrate 10 along with the first sections 11 and the second sections 12.

As shown in FIG. 15, the height h from the obverse surface 101 of the substrate 10 to the second surface 132 of the third sections 13 is greater than the thickness t of the wirings 41. In addition, the height h is greater than the length b of the second surface 132 in the direction in which the first electrodes 21 and the second electrodes 22 of the first element 201 are spaced apart.

Variation of Third Embodiment:

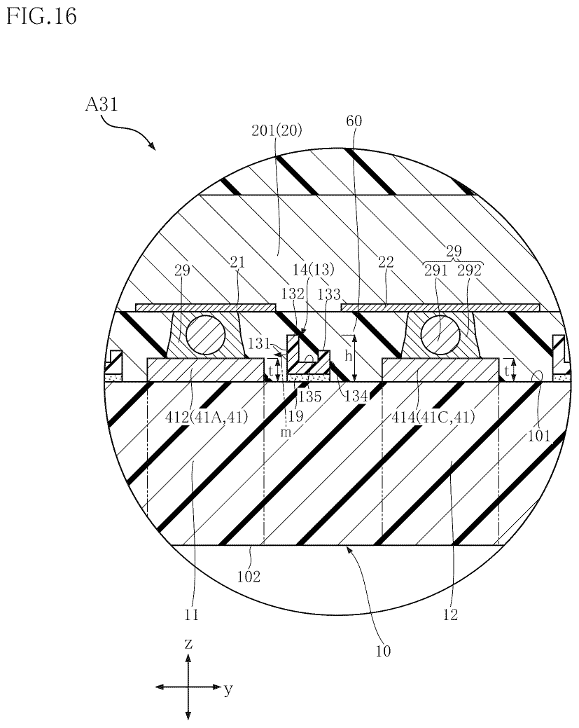

With reference to FIG. 16, the following describes a semiconductor device A31 that is a variation of the semiconductor device A30. Note that FIG. 16 shows the same position as FIG. 15.

The semiconductor device A31 differs from the semiconductor device A30 in the configuration of the third sections 13 of the substrate 10. As shown in FIG. 16, each third section 13 additionally has a third surface 133, a fourth surface 134, and a fifth surface 135. The third surface 133 and the fifth surface 135 face the same side as the obverse surface 101 of the substrate 10 in the thickness direction z. As viewed in the thickness direction z, the third surface 133 is located on the side opposite the second surface 132 with the fifth surface 135 interposed therebetween. In the thickness direction z, the third surface 133 is located between the second surface 132 and the fifth surface 135. The fourth surface 134 faces in a direction orthogonal to the thickness direction z and is connected to the third surface 133.

As shown in FIG. 16, each of the first surface 131 and the fourth surface 134 of the third sections 13 includes two regions spaced apart from each other. The direction in which the two regions are spaced apart is equal to the direction in which the first electrodes 21 and the second electrodes 22 of the first element 201 are spaced apart. One region of the first surface 131 and one region of the fourth surface 134 are connected to the fifth surface 135. That is, each third section 13 includes a ridge defined by the first surface 131, the second surface 132, and the fifth surface 135 and another ridge defined by the third surface 133, the fourth surface 134, and the fifth surface 135, and both of the ridges protrude from the obverse surface 101 of the substrate 10.

Next, effects of the semiconductor device A30 will be described.

The substrate 10 of the semiconductor device A30 includes the first sections 11, the second sections 12, and the third sections 13. The first sections 11 include portions of the obverse surface 101 of the substrate 10 and overlap with the relevant wirings 41 and the first electrodes 21 of the semiconductor element 20 as viewed in the thickness direction z. The second sections 12 include portions of the obverse surface 101 and overlap with the relevant wirings 41 and the second electrodes 22 of the semiconductor element 20 as viewed in the thickness direction z. Each third section 13 is located between a first section 11 and a second section 12 as viewed in the thickness direction z. The third section 13 has a first surface 131, and the normal direction m to the first surface 131 intersects (or orthogonal to) the thickness direction z. That is, the semiconductor device A30 allows the semiconductor element 20 to be more compact while preventing reduction of the dielectric strength of the semiconductor device A30. Further, the semiconductor device A30 has a similar configuration as the semiconductor device A10 and thus achieves the same effect by such a configuration.

In the semiconductor device A30, each third section 13 of the substrate 10 includes a ridge defined by the first surface 131 and the second surface 132 and protruding from the obverse surface 101 of the substrate 10. The manufacture of the semiconductor device A30 involves bonding the semiconductor element 20 to the wirings 41. In this process, the bonding layer 29 may melt and flow out of the wirings 41, in the case where solder is contained in the bonding layer 29 at least partly. The melted bonding layer 29, however, flows into contact with the first surfaces 131 and does not spread further. This can prevent the bonding layer 29 from short-circuiting the wirings 41. Further, as shown in FIG. 15, the height h from the obverse surface 101 to the second surface 132 is greater than the thickness of each wiring 41, which is preferable for sufficiently achieve this effect.

Each third sections 13 of the substrate 10 form a ridge protruding from the obverse surface 101 of the substrate 10. With this configuration, the second surface 132 of each third section 13 comes into contact with the semiconductor element 20 in the process of electrically bonding the semiconductor element 20 to the wirings 41 during the manufacture of the semiconductor device A30. This ensures that spaces are left between the wirings 41 and the first and second electrodes 21 and 22 of the semiconductor element 20.

With reference to the semiconductor device A31, each third section 13 of the substrate 10 additionally has the third surface 133, the fourth surface 134, and the fifth surface 135. This means that the substrate 10 of this variation has a greater creepage distance from the first section 11 to the second section 12 than that of the semiconductor device A30, and this enables the semiconductor device A31 to prevent reduction of the dielectric strength more effectively.

### Fourth Embodiment

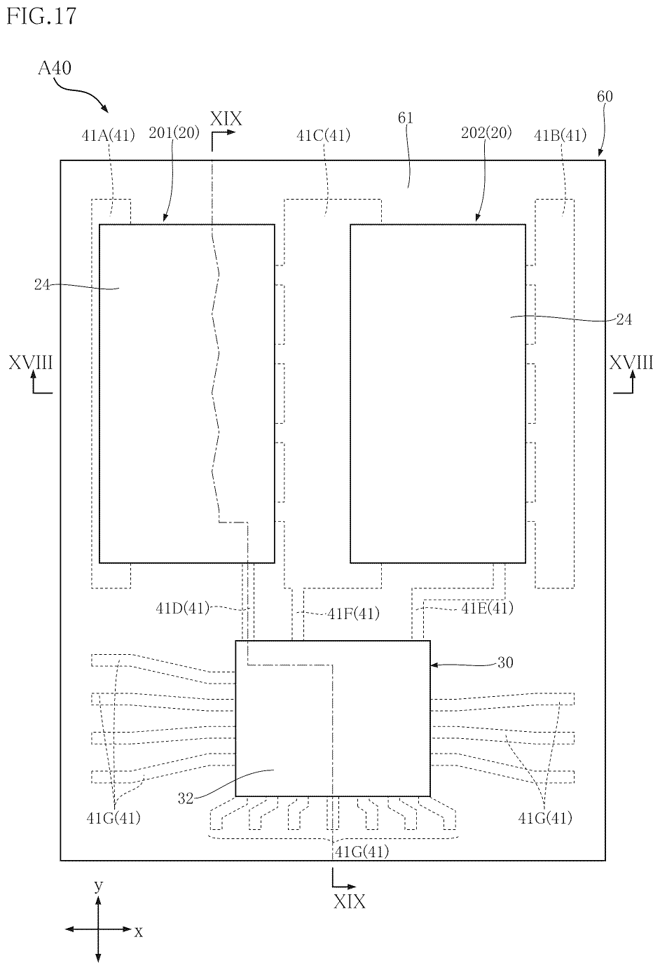

With reference to FIGS. 17 to 19, a semiconductor device A40 according to a fourth embodiment of the present disclosure will be described. In these figures, the same or similar elements as those of the semiconductor device A10 described above are denoted by the same reference numerals, and redundant descriptions are omitted.

The semiconductor device A40 differs from the semiconductor device A10 in the configurations of the semiconductor element 20 and the IC 30.

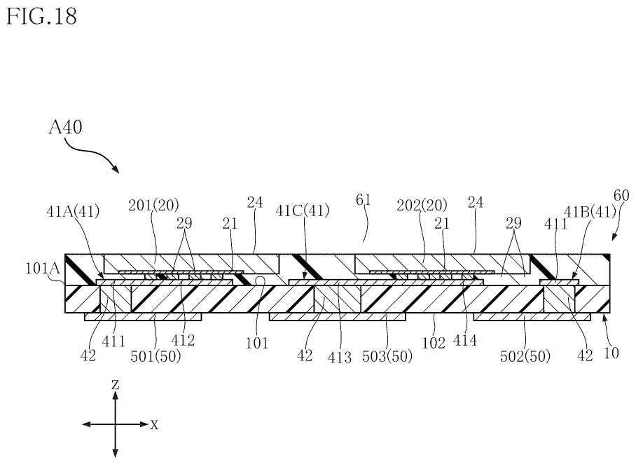

As shown in FIGS. 17 and 18, the semiconductor element 20 (the first element 201 and the second element 202) has an exposed surface 24. The exposed surface 24 faces the same side as the obverse surface 101 of the substrate 10 in the thickness direction z. The exposed surface 24 is exposed from the top surface 61 of the sealing resin 60. The exposed surface 24 is flush with the top surface 61.

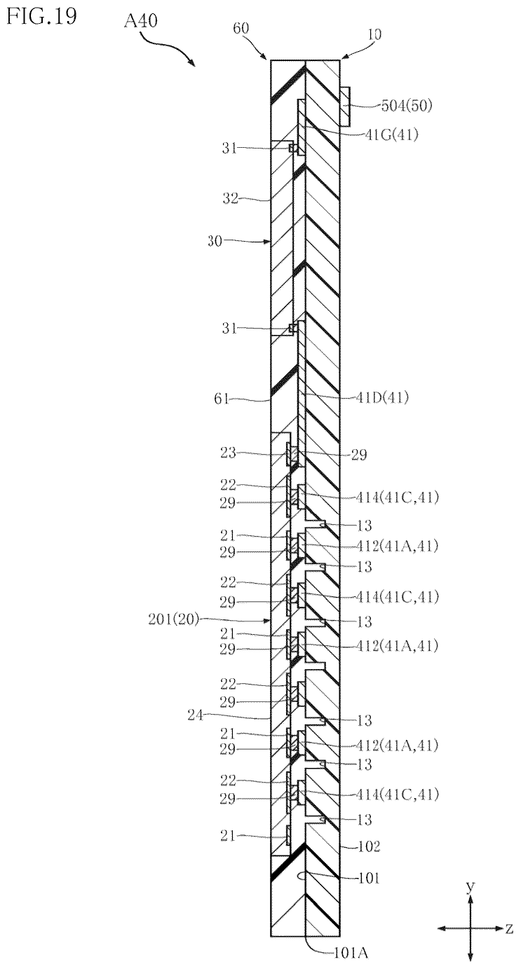

As shown in FIGS. 17 and 19, the IC 30 has an exposed surface 32. The exposed surface 32 faces the same side as the obverse surface 101 of the substrate 10 in the thickness direction z. The exposed surface 32 is exposed from the top surface 61 of the sealing resin 60. The exposed surface 32 is flush with the top surface 61. That is, the exposed surface 32 has the same position as the exposed surface 24 in the thickness direction z.

The third sections 13 of the substrate 10 shown in FIG. 19 may be similar in configuration to the third sections 13 of the semiconductor device A10. Alternatively, the third sections 13 of this embodiment may be similar in configuration to the third sections 13 of the semiconductor device A20 or the third sections 13 of the semiconductor device A30.

Next, effects of the semiconductor device A40 will be described.

The substrate 10 of the semiconductor device A40 includes the first sections 11, the second sections 12, and the third sections 13. The first sections 11 include portions of the obverse surface 101 of the substrate 10 and overlap with the relevant wirings 41 and the first electrodes 21 of the semiconductor element 20 as viewed in the thickness direction z. The second sections 12 include portions of the obverse surface 101 and overlap with the relevant wirings 41 and the second electrodes 22 of the semiconductor element 20 as viewed in the thickness direction z. Each third section 13 is located between a first section 11 and a second section 12 as viewed in the thickness direction z. The third section 13 has a first surface 131, and the normal direction m to the first surface 131 intersects (or orthogonal to) the thickness direction z. That is, the semiconductor device A40 allows the semiconductor element 20 to be more compact while preventing reduction of the dielectric strength of the semiconductor device A40. Further, the semiconductor device A40 has a similar configuration as the semiconductor device A10 and thus achieves the same effect by such a configuration.

In the semiconductor device A40, the semiconductor element 20 has the exposed surface 24 that is exposed from the top surface 61 of the sealing resin 60. This allows the semiconductor device A40 to more efficiently release the heat generated by the semiconductor element 20 during operation. In addition, the exposed surface 24 being flush with the top surface 61 is preferable for reducing the dimension of the sealing resin 60 in the thickness direction z. This contributes to the size reduction of the semiconductor device A40.

Mounting Structure for Semiconductor Element (First Embodiment)

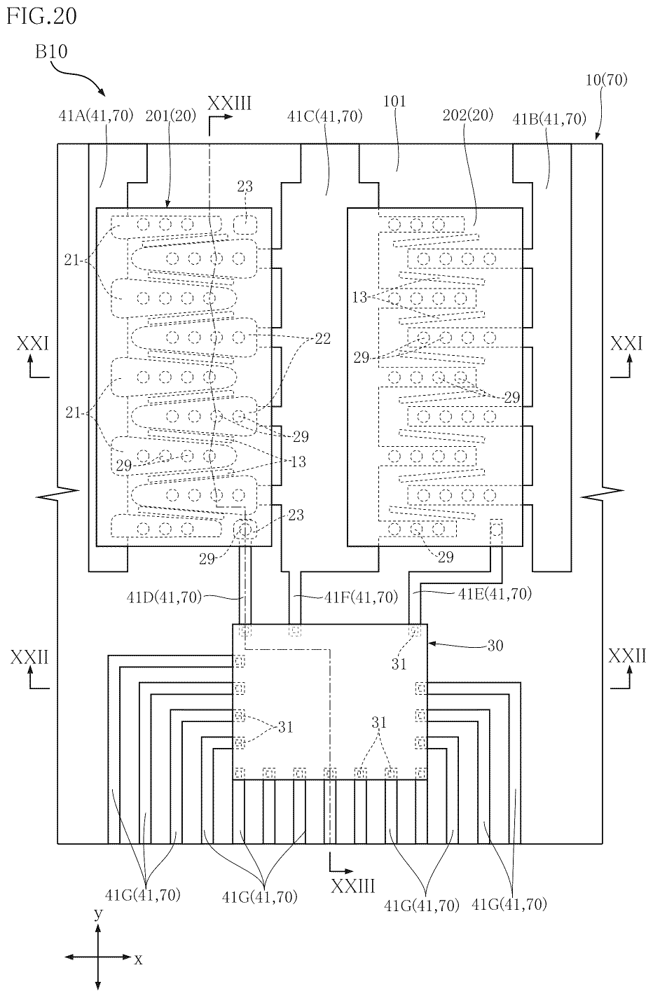

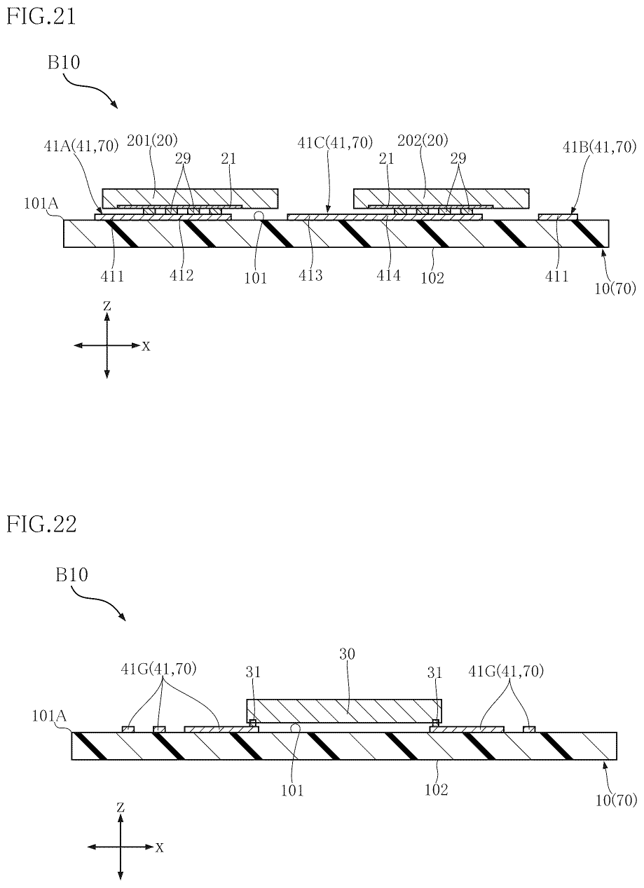

With reference to FIGS. 20 to 24, a mounting structure for a semiconductor device according to the first embodiment of the present disclosure (hereinafter “mounting structure B10”) will be described. In these figures, the same or similar elements as those of the semiconductor device A10 described above are denoted by the same reference numerals, and redundant descriptions are omitted.

As shown in FIG. 20, the mounting structure B10 includes a wiring board 70, a semiconductor element 20, a bonding layer 29, and an IC 30. The mounting structure B10 converts a direct-current power supplied from an external source to the mounting structure B10 into an alternating-current power by the semiconductor element 20. The alternating-current power is supplied to a driving target such as a motor.

As shown in FIGS. 20 to 23, the wiring board 70 includes a substrate 10 and a plurality of wirings 41. The wirings 41 include an input wiring 41A and a ground wiring 41B electrically connected to a direct-current power source external to the mounting structure B10. The wirings 41 also include an output wiring 41C electrically connected to a driving target, such as a motor external to the mounting structure B10. The wirings 41 also include a plurality of control wirings 41G electrically connected a control circuit (not shown) disposed on the wiring board 70. Electrical signals for driving the IC 30 are output from the control circuit. In addition, electrical signals from the IC 30 are input to the control circuit.

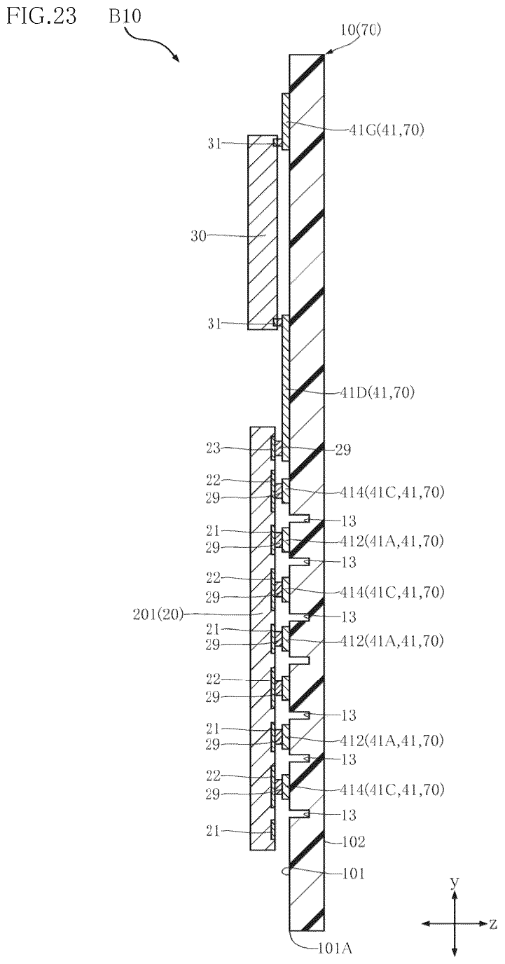

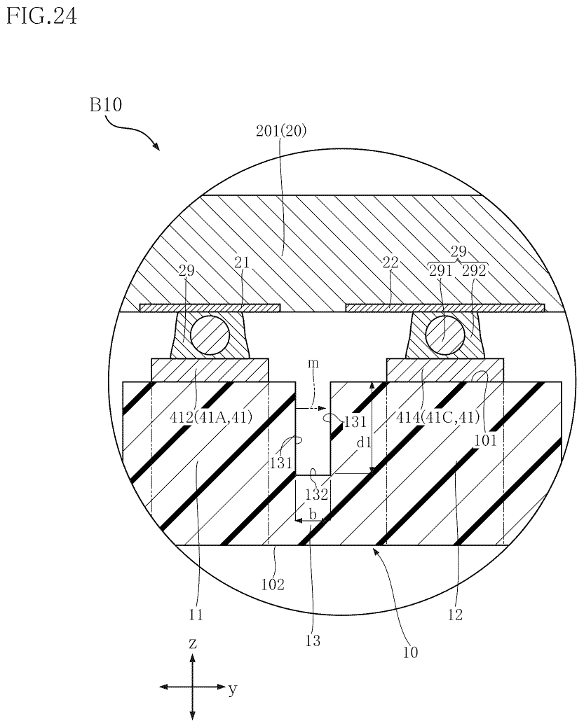

As shown in FIGS. 23 and 24, the substrate 10 includes a plurality of third sections 13. The third sections 13 have the same configuration as described for the third sections 13 of the semiconductor device A10. That is, each third section 13 includes a first surface 131 and a second surface 132 defining a trench recessed from the obverse surface 101. In another examples, the third sections 13 may have a configuration similar to the configuring of the third sections 13 of the semiconductor device A20 or the third sections 13 of the semiconductor device A30.

As shown in FIG. 24, the first surfaces 131 and the second surfaces 132 of the third section 13 are exposed to the outside of the mounting structure B10 along with the obverse surface 101 of the substrate 10.

Next, effects of the mounting structure B10 will be described.

The wiring board 70 of the mounting structure B10 includes the substrate 10 and the wirings 41. The substrate 10 includes the first sections 11, the second sections 12, and the third sections 13. The first sections 11 include portions of the obverse surface 101 of the substrate 10 and overlap with the relevant wirings 41 and the first electrodes 21 of the semiconductor element 20 as viewed in the thickness direction z. The second sections 12 include portions of the obverse surface 101 and overlap with the relevant wirings 41 and the second electrodes 22 of the semiconductor element 20 as viewed in the thickness direction z. Each third section 13 is located between a first section 11 and a second section 12 as viewed in the thickness direction z. The third section 13 has a first surface 131, and the normal direction m to the first surface 131 intersects (or orthogonal to) the thickness direction z. With this configuration, the creepage distance of the substrate 10 from a first section 11 to a second section 12 (the length of the path along the surface of the substrate 10) can be increased. This allows the spacing between the adjacent first and second electrodes 21 and 22 to be reduced to make the semiconductor element 20 more compact, without reducing the creepage distance of the substrate 10 from the wiring 41 overlapping with the first electrode 21 to the wiring 41 overlapping with the second electrode 22 as viewed in the thickness direction z. That is, the mounting structure B10 allows the semiconductor element 20 to be more compact while preventing reduction of the dielectric strength of the mounting structure B10.

In the mounting structure B10, each third section 13 of the substrate 10 includes a trench defined by the first surface 131 and the second surface 132 and recessed from the obverse surface 101 of the substrate 10. Constructing the mounting structure B10 involves bonding the semiconductor element 20 to the wirings 41. In this process, the bonding layer 29 may melt and flow out of the wirings 41, in the case where solder is contained in the bonding layer 29 at least partly. The melted bonding layer 29, however, flows into the trenches formed in the third sections 13 and does not spread further. This can prevent the bonding layer 29 from short-circuiting the wirings 41.

In addition, when the bonding layer 29 at least partly contains solder, a flux may be used in the process of electrically bonding the semiconductor element 20 to the wirings 41 and residue of the flux may remain on the wiring board 70. The flux contains metal particles containing the same metallic element as the bonding layer 29. For the mounting structure B10 having the obverse surface 101 of the substrate 10 exposed outside, presence of metal particles can cause ion migration to the wirings 41 when electric current flows through the wirings 41 and the semiconductor element 20 for a long time in a high temperate and humidity environment. Ion migration can be a cause of shorting between the wirings 41. Increasing the creepage distance of the substrate 10 between a first section 11 and a second section 12 is effective for preventing such ion migration.

Mounting Structure for Semiconductor Element (Second Embodiment)

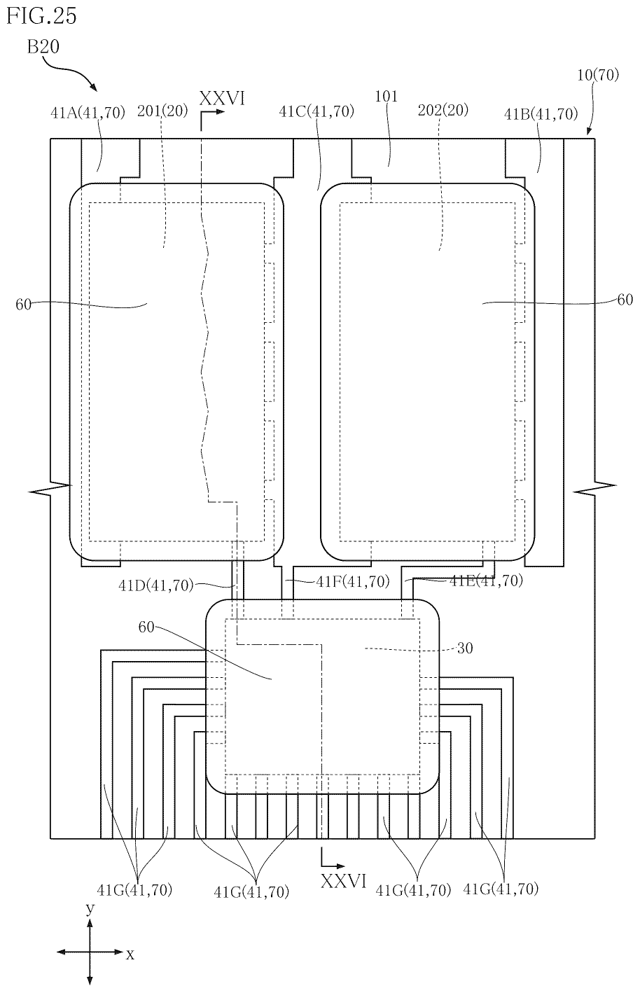

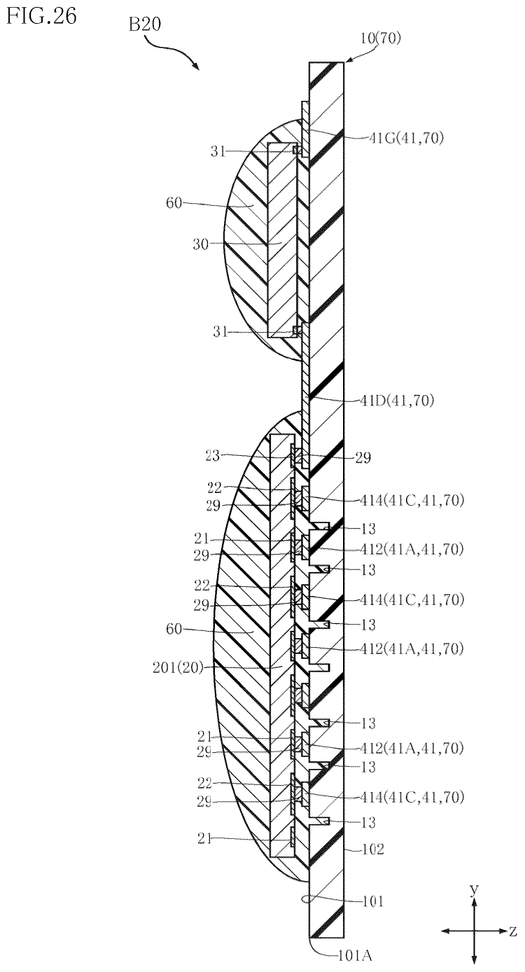

With reference to FIGS. 25 and 26, a mounting structure B20 according to the second embodiment of the present disclosure will be described. In these figures, the same or similar elements as those of the semiconductor device A10 and the mounting structure B10 described above are denoted by the same reference numerals, and redundant descriptions are omitted.

The mounting structure B20 differs from the mounting structure B10 in that a sealing resin 60 is additionally included.

As shown in FIGS. 25 and 26, the sealing resin 60 covers the semiconductor element 20, the IC 30, and a portion of each wiring 41. The sealing resin 60 may be made of the same material as that used for the underfill process. The sealing resin 60 is in contact with the first surface 131 of each third section 13 of the substrate 10. In the mounting structure B20, the sealing resin 60 fills out the trenches formed in the third sections 13.

Next, effects of the mounting structure B20 will be described.

The wiring board 70 of the mounting structure B20 includes the substrate 10 and the wirings 41. The substrate 10 includes the first sections 11, the second sections 12, and the third sections 13. The first sections 11 include portions of the obverse surface 101 of the substrate 10 and overlap with the relevant wirings 41 and the first electrodes 21 of the semiconductor element 20 as viewed in the thickness direction z. The second sections 12 include portions of the obverse surface 101 and overlap with the relevant wirings 41 and the second electrodes 22 of the semiconductor element 20 as viewed in the thickness direction z. Each third section 13 is located between a first section 11 and a second section 12 as viewed in the thickness direction z. The third section 13 has a first surface 131, and the normal direction m to the first surface 131 intersects (or orthogonal to) the thickness direction z. That is, the mounting structure B20 allows the semiconductor element 20 to be more compact while preventing reduction of the dielectric strength of the mounting structure B20.

The mounting structure B20 further includes the sealing resin 60 that covers the semiconductor element 20. This provides the semiconductor element 20 with protection against external factors. In addition, the sealing resin 60 is in contact with the first surface 131 of each third section 13 of the substrate 10. This is effective for more reliably preventing the ion migration described above.

The present disclosure is not limited to the embodiments described above. Various modifications in design may be made freely in the specific structure of each part of the present disclosure.

The present disclosure includes embodiments described in the following clauses.

Clause 1.

A semiconductor device comprising:
a substrate including an obverse surface facing in a thickness direction;
a first wiring and a second wiring disposed on the obverse surface; and
a semiconductor element including a first electrode facing the obverse surface, and a second electrode facing the obverse surface and adjacent to the first electrode,
wherein the first electrode is electrically bonded to the first wiring,
the second electrode is electrically bonded to the second wiring,
the substrate includes a first section, a second section, and a third section,
the first section includes a portion of the obverse surface and overlaps with the first wiring and the first electrode as viewed in the thickness direction,
the second section includes a portion of the obverse surface and overlaps with the second wiring and the second electrode as viewed in the thickness direction,
the third section is located between the first section and the second section as viewed in the thickness direction,
the third section includes a first surface, and
a normal direction to the first surface intersects the thickness direction.

Clause 2.

The semiconductor device according to Clause 1, wherein the third section includes a second surface facing a same side as the obverse surface in the thickness direction.

Clause 3.

The semiconductor device according to Clause 2, wherein the first surface and the second surface are opposite to the semiconductor element in the thickness direction with respect to the obverse surface.

Clause 4.

The semiconductor device according to Clause 3, wherein a length of the first surface in the thickness direction is greater than a length of the second surface in a direction in which the first electrode and the second electrode are spaced apart from each other.

Clause 5.

The semiconductor device according to Clause 4, wherein the third section includes a third surface facing the same side as the obverse surface in the thickness direction and spaced apart from the second surface as viewed in the thickness direction, and
the third surface is located between the obverse surface and the second surface in the thickness direction.

Clause 6.

The semiconductor device according to Clause 2, the first surface and the second surface are located between the obverse surface and the semiconductor element in the thickness direction.

Clause 7.

The semiconductor device according to Clause 6, wherein the third section includes a projection including the first surface and the second surface and made of an insulating material, and
the projection is bonded to the obverse surface.

Clause 8.

The semiconductor device according to any one of Clauses 1 to 7, wherein the third section extends in a direction orthogonal to the thickness direction.

Clause 9.

The semiconductor device according to Clause 8, wherein the first electrode and the second electrode extend in a direction orthogonal to the thickness direction.

Clause 10.

The semiconductor device according to any one of Clauses 1 to 9, wherein the third section is spaced apart from an outer edge of the obverse surface as viewed in the thickness direction.

Clause 11.

The semiconductor device according to any one of Clauses 1 to 10, further comprising a bonding layer electrically bonding the first wiring and the first electrode and also electrically bonding the second wiring and the second electrode,
wherein a composition of the bonding layer includes tin.

Clause 12.

The semiconductor device according to Clause 11, wherein the bonding layer includes a metal core and a metal layer covering the metal core, and
a composition of the metal layer include tin.

Clause 13.

The semiconductor device according to any one of Clauses 1 to 12, further comprising a sealing resin covering the semiconductor element, and
wherein the sealing resin is in contact with the first surface.

Clause 14.

The semiconductor device according to any one of Clauses 1 to 13, further comprising a terminal electrically connected to one of the first wiring and the second wiring,
wherein the substrate includes a reverse surface facing away from the obverse surface in the thickness direction, and
the terminal is disposed on the reverse surface.

Clause 15.

The semiconductor device according to Clause 14, further comprising a connecting wiring connected to one of the first wiring and the second wiring and to the terminal, and
the connecting wiring is embedded in the substrate.

Clause 16.

The semiconductor device according to any one of Clauses 1 to 15, further comprising an IC electrically connected to one of the first wiring and the second wiring for driving the semiconductor element,
wherein the semiconductor element includes a first element and a second element, and
the first electrode of the second element is electrically connected to the second electrode of the first element.

Clause 17.

A mounting structure for a semiconductor element, the mounting structure comprising:
a wiring board that includes a substrate with an obverse surface facing in a thickness direction, and a first wiring and a second wiring disposed on the obverse surface; and
a semiconductor element that includes a first electrode facing the obverse surface, and a second electrode facing the obverse surface and adjacent to the first electrode,
wherein the first electrode is electrically bonded to the first wiring,
the second electrode is electrically bonded to the second wiring,
the substrate includes a first section, a second section, and a third section,
the first section includes a portion of the obverse surface and overlaps with the first wiring and the first electrode as viewed in the thickness direction,
the second section includes a portion of the obverse surface and overlaps with the second wiring and the second electrode as viewed in the thickness direction,
the third section is located between the first section and the second section as viewed in the thickness direction,
the third section includes a first surface, and
a normal direction to the first surface intersects the thickness direction.

Clause 18.

The mounting structure according to Clause 17, further comprising a sealing resin covering the semiconductor element,
wherein the sealing resin is in contact with the first surface.

### REFERENCE NUMERALS

A10, A20, A30, A40: Semiconductor device
B10, B20: Mounting structure 10: Substrate
101: Obverse surface 101A: Outer edge
102: Reverse surface 11: First section
12: Second section 13: Third section
131: First surface 132: Second surface
133: Third surface 134: Fourth surface
135: Fifth surface 14: Projection
19: Adhesive layer 20: Semiconductor element
201: First element 202: Second element
21: First electrode 22: Second electrode
23: Third electrode 24: Exposed surface
29: Bonding layer 291: Metal core
292: Metal layer 30: IC
31: Electrode 32: Exposed surface
41: Wiring 41A: Input wiring
41B: Ground wiring 41C: Output wiring
41D: First gate wiring 41E: Second gate wiring
41F: Potential wiring 41G: Control wiring
411: First base portion 412: First extending portion
412A: First edge 413: Second base portion
414: Second extending portion 414A: Second edge
42: Connecting wiring 50: Terminal
501: Input terminal 502: Ground terminal
503: Output terminal 504: Control terminal
60: Sealing resin 61: Top surface
70: Wiring board z: Thickness direction
x: First direction y: Second direction m: Normal direction

1. A semiconductor device comprising:
a substrate including an obverse surface facing in a thickness direction;
a first wiring and a second wiring disposed on the obverse surface; and
a semiconductor element including a first electrode facing the obverse surface, and a second electrode facing the obverse surface and adjacent to the first electrode,
wherein the first electrode is electrically bonded to the first wiring,
the second electrode is electrically bonded to the second wiring,
the substrate includes a first section, a second section, and a third section,
the first section includes a portion of the obverse surface and overlaps with the first wiring and the first electrode as viewed in the thickness direction,
the second section includes a portion of the obverse surface and overlaps with the second wiring and the second electrode as viewed in the thickness direction,
the third section is located between the first section and the second section as viewed in the thickness direction,
the third section includes a first surface, and
a normal direction to the first surface intersects the thickness direction.

2. The semiconductor device according to claim 1, wherein the third section includes a second surface facing a same side as the obverse surface in the thickness direction.

3. The semiconductor device according to claim 2, wherein the first surface and the second surface are opposite to the semiconductor element in the thickness direction with respect to the obverse surface.

4. The semiconductor device according to claim 3, wherein a length of the first surface in the thickness direction is greater than a length of the second surface in a direction in which the first electrode and the second electrode are spaced apart from each other.

5. The semiconductor device according to claim 4, wherein the third section includes a third surface facing the same side as the obverse surface in the thickness direction and spaced apart from the second surface as viewed in the thickness direction, and
the third surface is located between the obverse surface and the second surface in the thickness direction.

6. The semiconductor device according to claim 2, the first surface and the second surface are located between the obverse surface and the semiconductor element in the thickness direction.

7. The semiconductor device according to claim 6, wherein the third section includes a projection including the first surface and the second surface and made of an insulating material, and
the projection is bonded to the obverse surface.

8. The semiconductor device according to claim 1, wherein the third section extends in a direction orthogonal to the thickness direction.

9. The semiconductor device according to claim 8, wherein the first electrode and the second electrode extend in a direction orthogonal to the thickness direction.

10. The semiconductor device according to claim 1, wherein the third section is spaced apart from an outer edge of the obverse surface as viewed in the thickness direction.

11. The semiconductor device according to claim 1, further comprising a bonding layer electrically bonding the first wiring and the first electrode and also electrically bonding the second wiring and the second electrode,
wherein a composition of the bonding layer includes tin.

12. The semiconductor device according to claim 11, wherein the bonding layer includes a metal core and a metal layer covering the metal core, and
a composition of the metal layer includes tin.

13. The semiconductor device according to claim 1, further comprising a sealing resin covering the semiconductor element, and
wherein the sealing resin is in contact with the first surface.

14. The semiconductor device according to claim 1, further comprising a terminal electrically connected to one of the first wiring and the second wiring,
wherein the substrate includes a reverse surface facing away from the obverse surface in the thickness direction, and
the terminal is disposed on the reverse surface.

15. The semiconductor device according to claim 14, further comprising a connecting wiring connected to one of the first wiring and the second wiring and to the terminal, and
the connecting wiring is embedded in the substrate.

16. The semiconductor device according to claim 1, further comprising an IC electrically connected to one of the first wiring and the second wiring for driving the semiconductor element,
wherein the semiconductor element includes a first element and a second element, and
the first electrode of the second element is electrically connected to the second electrode of the first element.

17. A mounting structure for a semiconductor element, the mounting structure comprising:
a wiring board that includes a substrate with an obverse surface facing in a thickness direction, and a first wiring and a second wiring disposed on the obverse surface; and
a semiconductor element that includes a first electrode facing the obverse surface and a second electrode facing the obverse surface and adjacent to the first electrode,
wherein the first electrode is electrically bonded to the first wiring,
the second electrode is electrically bonded to the second wiring,
the substrate includes a first section, a second section, and a third section,
the first section includes a portion of the obverse surface and overlaps with the first wiring and the first electrode as viewed in the thickness direction,
the second section includes a portion of the obverse surface and overlaps with the second wiring and the second electrode as viewed in the thickness direction,
the third section is located between the first section and the second section as viewed in the thickness direction,
the third section includes a first surface, and
a normal direction to the first surface intersects the thickness direction.

18. The mounting structure according to claim 17, further comprising a sealing resin covering the semiconductor element,
wherein the sealing resin is in contact with the first surface.
